(19) United States
(12) Patent Application Publication
(10) Pub. No.: US 2015/0226053 A1
(43) Pub. Date: Aug. 13, 2015

(54) REACTIVE MULTILAYER FOIL USAGE IN WIRED PIPE SYSTEMS

(71) Applicants: Stephan Mueller, Hannover (DE); Rene Schulz, Hambühren (DE); Robert Buda, Celle (DE); Henning Rahn, Celle (DE); Ingo Roders, Seelze (DE)

(72) Inventors: Stephan Mueller, Hannover (DE); Rene Schulz, Hambühren (DE); Robert Buda, Celle (DE); Henning Rahn, Celle (DE); Ingo Roders, Seelze (DE)

(73) Assignee: BAKER HUGHES INCORPORATED, Houston, TX (US)

(21) Appl. No.: 14/178,856

(22) Filed: Feb. 12, 2014

(51) Int. Cl. E21B 47/01; H05K 5/04; H05K 5/06

(52) U.S. Cl. CPC E21B 47/011; H05K 5/065; H05K 5/04

(57) ABSTRACT

A sealed chamber for disposal in a wired pipe segment includes a base element, electronics supported in a chamber in the base element and a sealing layer that prevents the electronics inside the chamber from harmful gases and fluids, the sealing layer comprising a reactive multi-layer foil material (RMFM).

### BACKGROUND OF THE INVENTION

During subterranean drilling and completion operations, a pipe or other conduit is lowered into a borehole in an earth formation during or after drilling operations. Such pipes are generally configured as multiple pipe segments to form a “string”, such as a drill string or production string. As the string is lowered into the borehole, additional pipe segments are coupled to the string by various connection mechanisms, such as threaded couplings.

Various power and/or communication signals may be transmitted through the pipe segments via a “wired pipe” configuration. Such configurations include electrical, optical or other conductors extending along the length of selected pipe segments or string segments. The conductors are operably connected between pipe segments by a variety of configurations.

One such configuration includes a threaded male-female configuration often referred to as a pin box connection. The pin box connection includes a male member, i.e., a “pin end” that includes an exterior threaded portion, and a female member, i.e., a “box end”, that includes an interior threaded portion and is configured to receive the pin in a threaded connection.

Some wired pipe configurations include a transmission device mounted on the tip of the pin end as well as in the box end. The transmission device, or “coupler,” can transmit power, data or both to an adjacent coupler. The coupler in the pin end is typically connected via a coaxial cable or other means to the coupler in the box end.

The drilling environment is harsh and exposure of some or all of electronic elements described above may result in damage to those elements.

### BRIEF DESCRIPTION OF THE INVENTION

Disclosed herein is sealed chamber for disposal in a wired pipe segment that includes a base element, electronics supported in a chamber in the base element and a sealing layer that prevents the electronics inside the chamber from harmful gases and fluids, the sealing layer comprising a reactive multi-layer foil material (RMFM).

Also disclosed is an electronic frame for use in a downhole component coupling mechanism in a segmented wired pipe system. The frame includes a first frame element including at least one retaining structure configured to retain electronics; and a sealing layer forming a seal with the first frame element, the sealing layer preventing downhole elements from contacting the electronics, the sealing layer sealed to the frame by a reactive multi-layer foil material (RMFM) connection.

### BRIEF DESCRIPTION OF THE DRAWINGS

The following descriptions should not be considered limiting in any way. With reference to the accompanying drawings, like elements are numbered alike:

FIG. 1 depicts an exemplary embodiment of a wired pipe segment of a well drilling and/or logging system;

FIG. 2 depicts an exemplary embodiment of a box connector of the segment of FIG. 1;

FIG. 3 depicts an exemplary embodiment of a pin connector of the segment of FIG. 1;

FIG. 4 is a perspective view of a sealed chamber;

FIG. 5 is cut-away side view of the sealed chamber of FIG. 4;

FIG. 6 is a perspective view of a repeater element; and

FIGS. 7A-7B show a sealing hatch according to one embodiment.

### DETAILED DESCRIPTION OF THE INVENTION

A detailed description of one or more embodiments of the disclosed apparatus and method are presented herein by way of example and not limitation with reference to the Figures.

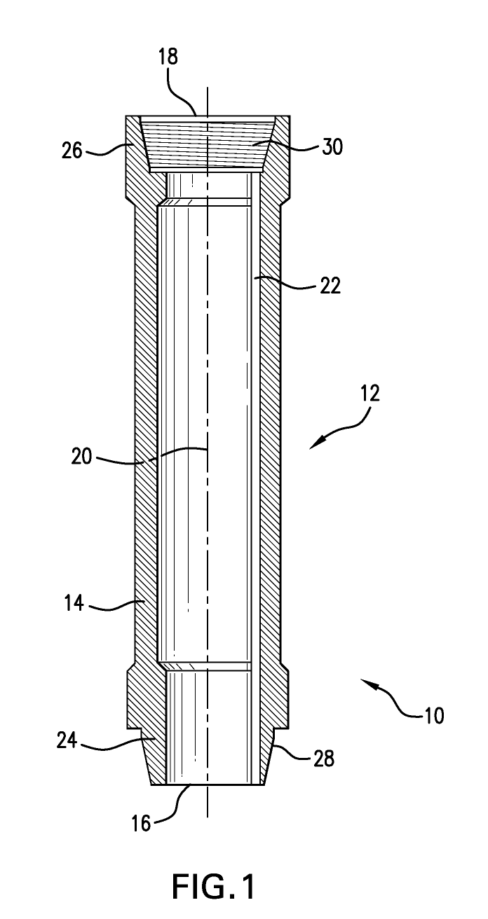

Referring to FIG. 1, an exemplary embodiment of a portion of a well drilling, logging and/or production system 10 includes a conduit or string of drill pipe segments 14 (generally denoted as string 12), such as a drillstring or production string, that is configured to be disposed in a borehole for performing operations such as drilling the borehole, making measurements of properties of the borehole and/or the surrounding formation downhole, or facilitating gas or liquid production.

For example, during drilling operations, drilling fluid or drilling “mud” is introduced into the string 12 from a source such as a mud tank or “pit” and is circulated under pressure through the string, for example via one or more mud pumps. The drilling fluid passes into the string and is discharged at the bottom of the borehole through an opening in a drill bit located at the downhole end of the string. The drilling fluid circulates uphole between the string and the borehole wall and is discharged into the mud tank or other location.

The wired pipe segment 14 has an uphole end 18 and a downhole end 16. As described herein, “uphole” refers to a location near the point where the drilling started relative to a reference location when the segment 14 is disposed in a borehole, and “downhole” refers to a location away from the point where the drilling started along the borehole relative to the reference location. It shall be understood that the uphole end 18 could be below the downhole end 16 without departing from the scope of the disclosure herein. In this same vein, as a plurality of segments are joined to form a string, the directions related to up and downhole described may also refer to the resultant string.

At least an inner bore or other conduit 20 extends along the length of each segment 14 to allow drilling mud or other fluids to flow therethrough. A transmission line 22 is located within the inner bore 20 of segment 14. In one embodiment, the transmission line enters the inner bore 20 via an inlet as described below. In one embodiment, the transmission line 22 is a coaxial cable. In another embodiment, the transmission line 22 is formed of any manner of carrying power or data, including, for example, a twisted pair. In the case where the transmission line 22 is a coaxial cable it may include an inner conductor surrounded by a dielectric material. The coaxial cable may also include a shield layer that surrounds the dielectric material. In one embodiment, the shield layer is electrically coupled to an outer conductor that may be formed, for example, by a rigid or semi-rigid tube of a conductive material.

The segment 14 includes a downhole connection 24 and an uphole connection 26. The segment 14 is most commonly configured so that the uphole connection 26 is positioned at an uphole location relative to the downhole connection 24. The downhole connection 24 includes a male connection portion 28 having an exterior threaded section, and is referred to herein as a “pin end” 24. The uphole connection 26 includes a female connection portion 30 having an interior threaded section, and is referred to herein as a “box end” 26.

The pin end 24 and the box end 26 are configured so that the pin end 24 of one wired pipe segment 14 can be disposed within the box end 26 of another wired pipe segment 14 to effect a fixed connection therebetween to connect the segment 14 with another adjacent segment 14 or other downhole component to form a drill string. In one embodiment, the exterior of the male connection portion 28 and the interior of the female connection portion 30 are tapered. Although the pin end 24 and the box end 26 are described has having threaded portions, the pin end 24 and the box end 26 may be configured to be coupled using any suitable mechanism, such as bolts or screws or an interference fit.

In one embodiment, the system 10 is operably connected to a downhole or surface processing unit which may act to control various components of the system, such as drilling, logging and production components or subs. Other components include machinery to raise or lower segments 14 and operably couple segments 14, and transmission devices. The downhole or surface processing unit may also collect and process data generated by the system 10 during drilling, production or other operations.

As described herein, “drillstring” or “string” refers to any structure or carrier suitable for lowering a tool through a borehole or connecting a drill bit to the surface, and is not limited to the structure and configuration described herein. For example, a string could be configured as a drillstring, hydrocarbon production string or formation evaluation string. The term “carrier” as used herein means any device, device component, combination of devices, media and/or member that may be used to convey, house, support or otherwise facilitate the use of another device, device component, combination of devices, media and/or member. Exemplary non-limiting carriers include drill strings of the coiled tube type, of the jointed pipe type and any combination or portion thereof. Other carrier examples include casing pipes, wirelines, wireline sondes, slickline sondes, drop shots, downhole subs, BHA's and drill strings.

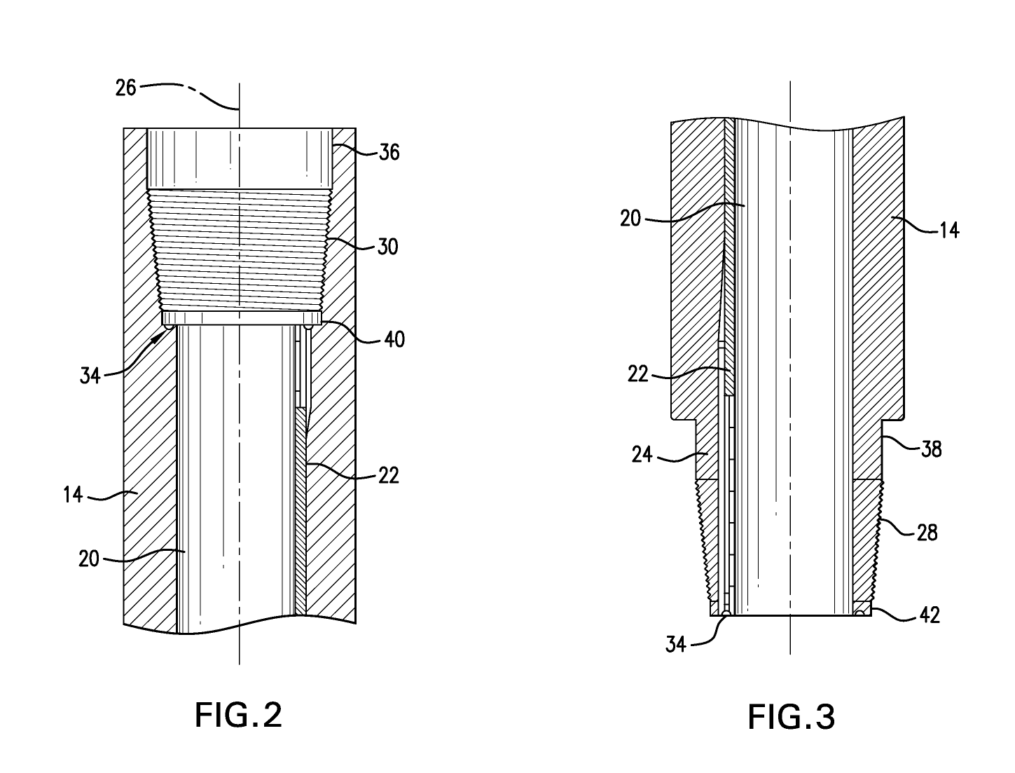

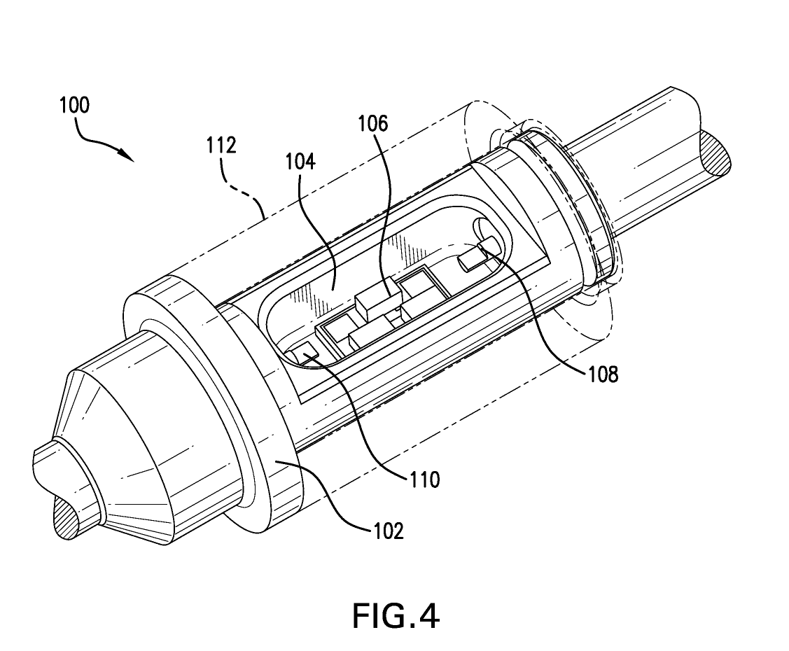

Referring to FIGS. 2 and 3, the segment 14 includes at least one transmission device 34 (also referred to as a “coupler” herein) disposed therein and located at the pin end 24 and/or the box end 26. The transmission device 34 is configured to provide communication of at least one of data and power between adjacent segments 14 when the pin end 24 and the box end 26 are engaged. The transmission device 34 may be of any suitable type, such as an inductive coil, direct electrical (e.g., galvanic) contacts and an optical connection ring. The coupler may be disposed at the inner or outer shoulder. Further, the transmission device 34 may be a resonant coupler. It shall be understood that the transmission device 34 could also be included in a repeater element disposed between adjacent segments 14 (e.g., within the box end). In such a case, the data/power is transmitted from the transmission device in one segment, into the repeater. The signal may then be passed “as is,” amplified, and/or modified in the repeater and provided to the adjacent segment 14.

Regardless of the configuration, it shall be understood that each transmission device 34 can be connected to one or more transmission lines 22. Embodiments disclosed herein are directed to how the transmission lines 22 can be formed and disposed in a segment 14. In one embodiment, the transmission line 22 is capable of withstanding the tensile, compression and torsional stresses and superimposed dynamic accelerations typically present in downhole tools when exploring oil, gas or geothermal wells. In one embodiment, a channel is formed in the segment 14 between the location of a portion of the transmission device 34 and the inner bore 20. The transmission line 22 is partially contained in the inner bore 20 and the channel. In one embodiment, the channel is gun drilled into the pipe segment 14.

In one embodiment, the transmission line 22 includes a wire channel (e.g., an outer protective layer) and a transmission element. The transmission element can be selected from one of coaxial cable, twisted pair wires, and individual wires. The following description is presented with respect to coaxial wire but it shall be understood that the teachings herein are applicable to any type of transmission element. In one embodiment, tension is created in the transmission element with respect to one or both the wire channel and the body of the segment 14. This tension may help to abate independent motion between the transmission element and the wire channel.

In some cases it may be desirable to attach electronic components close to the transmission device 34. Due to the harsh drilling environment, the electronic components need to be sealed from mud and other elements. The dimensions of the thread connection limit the space available for the design of encapsulated electronic components or connectors. In one embodiment, a reactive multi-layer foil material (RMFM) sealed connection may be used to seal such a compartment in which such electronics are sealed. An RMFM is formed of two mutually reactive metals (e.g., aluminium and nickel) formed in thin layers to create a laminated foil. Application of a heat pulse causes the aluminium and nickel to undergo self-sustaining exothermic reaction, producing an intermetallic compound nickel aluminide (NiAl) that can seal two elements together. The heat pulse may be provided by a bridge wire, a laser pulse, an electric spark, a flame, or by other means. The reaction occurs in solid and liquid phase only, without releasing any gas. Other examples of multilayer combinations include aluminium-titanium and titanium-amorphous silicon.

Such a seal may be smaller than an elastomeric seal. Also, a seal based on an RMFM connection may have improved reliability due to its ability to endure high temperature and pressure conditions. In some embodiments a seal that is electrical conductive might be desirable and RMFMs may be electrically conductive in some instances.

In some cases, a RMFM sealed connection requires the application of less heat than welding and may allow for connections in positions that could not be reached by a welding machine. Further, the processing time as compared to welding could be reduced and be performed without outgassing.

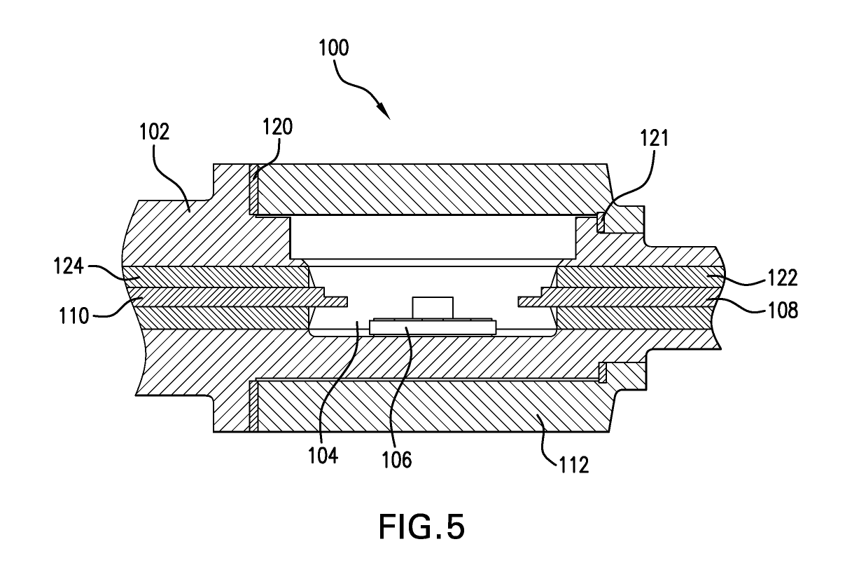

FIG. 4 illustrates a sealed cavity 100 that may be formed by the use of an RMFM seal. The cavity 100 includes a main body 102 that includes an electronics location 104 where electronics 106 are located. The electronics 106 may be used to condition or otherwise modify a signal passing between first and second connectors 108, 110 that are illustrated as wires in FIG. 4. The electronics should be sealed from drilling mud. Thus, in one embodiment, a sleeve 112 is provided that covers the electronics 106. In one embodiment, the sleeve 112 is sealed to the main body 102 by one or more RMFM connections. Using an RMFM connection may allow for sealing the electronics 106 without exposing them to possibly damaging welding head and may last longer than an elastomeric seal. The electronics 106 can include any type of electrical components and can be used for any number of different purposes. For instance, electronics 106 could be used, for example, in a repeater element that boosts a signal as it traverses one or more wired pipe segments. In another embodiment, the electronic 106 could be used to match the impedance of different circuits connected to first and second connectors 108, 110. For instance, the electronics could match the impedance of a transmission device 34 to a transmission line 22 (FIG. 3).

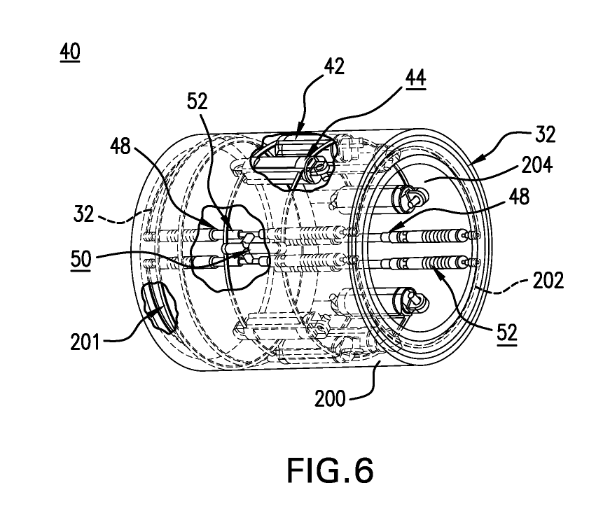

FIG. 5 is a cut-away side view of the FIG. 4 illustrates a sealed cavity 100 shown in FIG. 4. The cavity 100 is formed main body 102 with a cavity or electronics location 104 into which electronics 106 are disposed. As above, the electronics 106 may be used to condition or otherwise modify a signal passing between first and second connectors 108, 110. As illustrated, the first and second connectors 108, 110 are electrically insulated from the main body by insulating materials 122, 124, respectively. To form a seal between the sleeve 112 and the main body 102, two RMFM connections or seals 120, 121 are formed. For example, the RMFM seals could be formed by disposing rings of a RMFM at the locations shown of seals 120, 121 and then exposing those regions to a heat pulse from one or more of: a bridge wire, a laser pulse, an electric spark, a flame, or by other means.

In the preceding examples, an RMFM seal in a electronics cavity 100 has been described. It shall be understood, however, that the seal could be used in any component used in a down-hole environment.

Signal repeaters have been used to enhance transmission of power and communications between components over a telemetry line or system. Such repeaters are provided to reduce signal loss during transmission of data from downhole components to the surface.

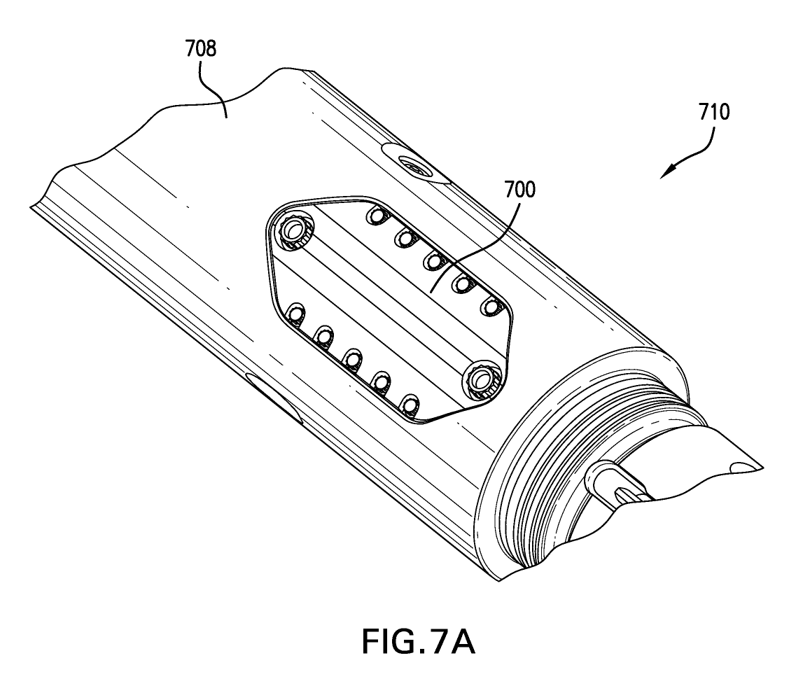

FIG. 6 illustrates an embodiment of a pressure-sealed and mechanically robust electronic frame 40 configured to be disposed within a coupling assembly between downhole components, e.g., within a space formed within the pin 24 and/or the box 26. In one embodiment, the electronic frame includes electronics configured to facilitate wired pipe telemetry or other communications. The frame is mechanically distinct and separate from the coupling assembly and the downhole components, and is configured to be secured at least axially based on encapsulation of the frame by the coupling assembly and/or the downhole components. Thus, the frame does not need to be directly sealed or adhered to the connection/components, but rather can rely upon the already existing sealing engagement between the components (e.g., the box-pin connection).

As shown in FIG. 6, the frame 40 is configured to support electronics for drill pipes, downhole tools and other downhole components. Exemplary electronics include repeater electronics of a signal transmission system configured to transmit power and/or communications between downhole components. For example, the frame 40 includes recesses, chambers or other retaining structures to house repeater components (e.g., electronics and sealing components) for transmitting signals between components. Such exemplary repeater components include batteries 42, control electronics 44 such as multi-chip modules (MCMs), and transmission devices 34 such as coupler rings, antennas, electrical contacts and inductive coupling elements. As above, the transmission devices may be of any suitable type, such as an inductive coil, direct electrical contacts and an optical connection ring. Other exemplary components include transmission components such as connectors 48, interfaces 50 and various sealing components 52 such as glass seals and antenna seals.

The frame 40 includes a fluid conduit 204 that allows for fluid to pass through it. In one embodiment, the transmission element 32 is sized and configured such that the fluid (e.g. drilling mud) can pass through it.

According to one embodiment, the frame 40 includes an outer sealing layer 201 that seals elements in the recesses, chamber or other retaining structures of the of the frame 40. In one embodiment, RMFM seals 201, 202 seal the frame and the outer sealing layer 201 to protect elements in the recesses. It shall be understood that any of the batteries, control electronics 44 or other devices carried by the frame 40 could themselves be in sealed chambers formed as described above.

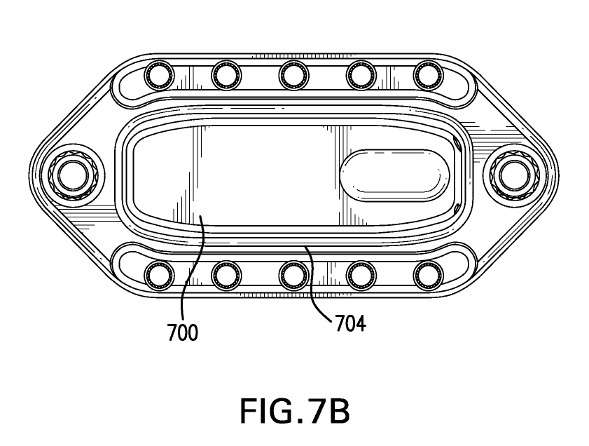

In the above description a full circumferential seal has been illustrated. It shall understood, and with reference now to FIGS. 7A-7B, that a bead 704 of RMFM may be used to seal a hatch 700 over a cavity defined by the outer surface 708 of the downhole tool 710.

While the invention has been described with reference to example embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the claims.

What is claimed is:

1. A sealed chamber for disposal in a wired pipe segment, the sealed chamber comprising:
a base element;
electronics supported in a chamber in the base element; and
a sealing layer that prevents the electronics inside the chamber from harmful gases and fluids, the sealing layer comprising a reactive multi-layer foil material (RMFM).

2. The sealed chamber of claim 1, wherein the RMFM is formed of aluminum and nickel, aluminum and titanium, or titanium and amorphous silicon.

3. The sealed chamber of claim 1, wherein the RMFM is exposed to a heat pulse.

4. The sealed chamber of claim 3, wherein the heat pulse is provided by one or more of: a bridge wire, a laser pulse, an electric spark, and a flame.

5. An electronic frame for use in a downhole component coupling mechanism in a segmented wired pipe system, comprising:
a first frame element including at least one retaining structure configured to retain electronics; and
a sealing layer forming a seal with the first frame element, the sealing layer preventing downhole elements from contacting the electronics, the sealing layer sealed to the frame by a reactive multi-layer foil material (RMFM) connection.

6. The sealed chamber of claim 5, wherein the RMFM is formed of aluminum and nickel, aluminum and titanium, or titanium and an amorphous silicon.

7. The sealed chamber of claim 6, wherein the RMFM is exposed to a heat pulse.

8. The sealed chamber of claim 7, wherein the heat pulse is provided by one or more of: a bridge wire, a laser pulse, an electric spark, and a flame.

9. The electronic frame of claim 5, further comprising a fluid conduit formed by the frame element configured to provide fluid communication there through.
